(19) United States
(12) Patent Application Publication
(10) Pub. No.: US 2004/0218648 A1
(43) Pub. Date: Nov. 4, 2004

(54) Laser diode and method of manufacturing the same using self-align process

(75) Inventors: Youn-joon Sung, Gyeonggi-do (KR); Joon-seop Kwak, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 10/813,157

(22) Filed: Mar. 31, 2004

(30) Foreign Application Priority Data
Apr. 29, 2003 (KR) 10-2003-0027075

(51) Int. Cl. H01S 5/00

(52) U.S. Cl. 372/46

(57) ABSTRACT

Provided is a laser diode wherein a buried layer covers a ridge structure on an upper cladding layer, and a protective layer having an adhesive property to the buried layer and a thermal conductivity higher than that of the buried layer is formed on the buried layer. The portions of the buried layer and the protective layer corresponding to the top of the ridge are opened so that an upper electrode contacts a semiconductor material layer formed on the ridge through the opened portions of the buried layer and the protective layer.

### BACKGROUND OF THE INVENTION

This application claims the priority of Korean Patent Application No. 2003-27075, filed on Apr. 29, 2003, in the Korean Intellectual Property Office, which is incorporated herein in its entirety by reference.

1. Field of the Invention

The present invention relates to a method of manufacturing a laser diode, and more particularly, to a method of manufacturing a laser diode using a self-align process.

2. Description of the Related Art

The semiconductor laser diode is generally used to transfer, record, and read data in the field of communications, such as optical communications, or in devices, such as a compact disk player (CDP) and a digital versatile disk player (DVDP).

Since a semiconductor laser diode can maintain the oscillation characteristic of a laser beam in a limited space, can be formed in a small size, and requires a small critical current value for oscillating the laser beam, the semiconductor laser diode is widely used in optical communications, multiplex communications, and universal communications. With the increase of the number of industrial fields to which the semiconductor laser diode is applied, the demand for a semiconductor laser diode having a smaller critical current value increases. In other words, a semiconductor laser diode having excellent characteristics, such as low laser oscillation at a low current and long lifespan, is needed.

FIG. 1 is a sectional view illustrating a conventional semiconductor laser diode, which has a ridge waveguide structure for reducing a critical current value of laser oscillation. Referring to FIG. 1, an n-GaN lower contact layer 12, which is separated into a first region R1 and a second region R2, is stacked on a sapphire substrate 10. An n-GaN/AIGaN lower cladding layer 24, an n-GaN lower waveguide layer 26, a InGaN active layer 28, a p-GaN upper waveguide layer 30, a p-GaN/AIGaN upper cladding layer 32 are sequentially stacked in the first region R1 of the n-GaN lower contact layer 12. Here, the refractive indexes of the n-GaN/AIGaN lower cladding layer 24 and the p-GaN/AIGaN upper cladding layer 32 are respectively smaller than the refractive indexes of the n-GaN lower waveguide layer 26 and the p-GaN upper waveguide layer 30. In addition, the refractive indexes of the n-GaN lower waveguide layer 26 and the p-GaN upper waveguide layer 30 are respectively smaller than the refractive index of the active layer 28. A protruding ridge 32a having a predetermined width is formed at the center of the upper portion of the p-GaN/AIGN upper cladding layer 32 in order to provide a ridge waveguide structure, and a p-GaN upper contact layer 34 is formed on the ridge 32A. A buried layer 36, as a passivation layer having a contact hole 36A, is formed on the p-GaN/AIGaN upper cladding layer 32. The contact hole 36A of the buried layer 36 corresponds to the top portion of the upper contact layer 34 that is formed on the ridge 32A, and the edge of the contact hole 36A overlaps the edge of the upper surface of the upper contact layer 34.

A p-type upper electrode 38 contacting the upper contact layer 34 through the contact hole 36A of the buried layer 36 is formed on the buried layer 36. An n-type lower electrode 37 is formed in the second region R2 of the n-GaN lower contact layer 12, and the height of the n-type lower electrode 37 being smaller than the height of the first region R1.

The ridge waveguide structure formed on the upper cladding layer 32 limits the currents that are injected to the active layer 28 in order to limit the width of the resonance area for laser oscillation in the active layer 28. Thus, a transverse mode is stable and the operation current is lowered.

In the process of manufacturing the ridge waveguide structure, one of the methods of forming the contact hole, which corresponds to the upper surface of the ridge, on the buried layer, which covers the edge of the upper cladding layer, is a photolithography method using a mask. However, the photolithography method has the disadvantage of low precision, and impossibility to secure a sufficient contact area between the upper contact layer and the p-type upper electrode. Therefore, the operation voltage of the device is increased, and the heat from the operation of the device cannot be exhausted efficiently.

Accordingly, a self-align process is preferred in order to form the contact hole of a laser diode. PCT No. WO 2000/52796 discloses a method of forming a self-aligned contact hole by a lift-off operation that uses a selective dissolution of materials. However, in performing the lift-off operation, when the thickness of the buried layer is large, the lift-off operation cannot be performed so that the thickness of the buried layer is limited. More specifically, since the lift-off operation removes the target layer using the solubility difference between materials, there is a limit in selecting the materials.

Another method using the self-align process forms a contact hole corresponding to the upper surface of a ridge in a buried layer by using etch back. In this process, a planarized photoresist is formed on the surface of a wafer on which a ridge and a buried layer are sequentially formed, and the mask on the upper portion of the ridge is removed by etch back using dry etching. Accordingly, a contact hole corresponding to the upper portion of the ridge is formed. In this process, an etch stop layer is absent between the buried layer and the ridge so that it is difficult to determine the time for stopping the etching. In addition, the buried layer on the ridge, which is partially exposed due to the etch back using the dry etching, should be removed by wet etching, because the dry etching damages the upper contact layer on the upper portion of the ridge. However, when the wet etching is performed, the etchant penetrates through the interface between the photoresist and the buried layer so that the buried layer is excessively etched laterally of the ridge.

### SUMMARY OF THE INVENTION

The present invention provides a method of manufacturing a laser diode such that a ridge in a ridge waveguide structure is protected in order to efficiently prevent the increases of a leakage current and an operation current.

According to an aspect of the present invention, there is provided a laser diode comprising a lower material layer formed on a substrate, a resonance layer formed on the lower material layer, an upper material layer formed on the resonance layer and having a ridge at the top, a buried layer having a contact hole corresponding to the ridge formed on the upper material layer, a protective layer formed by a material different from the material of the buried layer, while having an opening corresponding to the contact hole of the buried layer, and an upper electrode formed on the protective layer to contact to the upper surface of the ridge through the contact hole.

According to another aspect of the present invention, there is provided a method of manufacturing a laser diode comprising: forming a laser oscillating structure including a substrate, a resonance layer on the substrate, and cladding layers formed on and under the resonance layer that has a ridge protruding to a predetermined height; forming a buried layer on top of the structure to cover the surface of the ridge; sequentially forming a protective layer and an etch back material layer on the surface of the buried layer; etching the etch back material layer by an etch back process to a predetermined depth to expose a portion of the protective layer at the upper direction of the ridge; removing the portion of the protective layer, which is not covered by the etch back material layer, by using an etchant to form an opening, which exposes a portion of the surface of the buried layer on the ridge; removing the etch back material layer remained on the buried layer; forming a contact hole by etching the portion of the buried layer, which is exposed through the opening of the protective layer; and forming an upper electrode that contacts to the top surface of the ridge through the contact hole on the protective layer.

According to the present invention, the protective layer that protects the buried layer is formed on the buried layer as a passivation layer in the ridge waveguide structure. Therefore, leakage current around the ridge can be efficiently prevented, and the operation current of the ridge waveguide structure is lowered. The protective layer operates as an etch stop layer in etching the layers. In particular, the protctive layer prevents over etching of the buried layer so that a stable waveguide structure can be obtained.

### BRIEF DESCRIPTION OF THE DRAWINGS

The above aspects and advantages of the present invention will become more apparent by describing in detail exemplary embodiments thereof with reference to the attached drawings in which:

FIG. 1 is a sectional view illustrating a conventional laser diode;

FIG. 2 is a sectional view illustrating a laser diode according to an embodiment of the present invention;

FIGS. 3A through 3L are sectional views illustrating a method of manufacturing a laser diode according to an embodiment of the present invention;

FIG. 4A is an SEM photograph illustrating a sectional view of a ridge of a conventional laser diode;

FIG. 4B is an SEM photograph illustrating a sectional view of a ridge of a laser diode according to the embodiment of the present invention; and

FIG. 5 is an SEM photograph illustrating a sectional view of a laser diode according to the embodiment of the present invention.

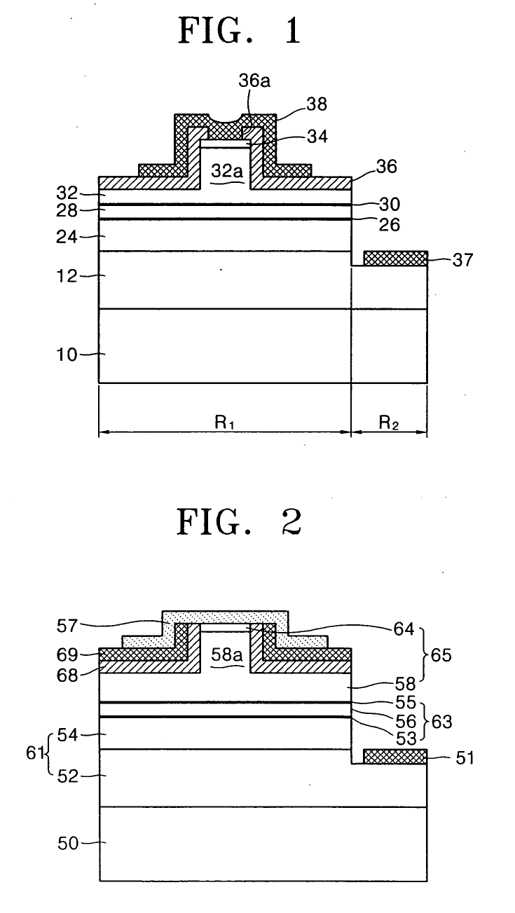

### DETAILED DESCRIPTION OF THE INVENTION

The present invention will now be described more fully with reference to the accompanying drawings, in which preferred embodiments of the invention are shown. In the drawings, the size and the thickness of layers and regions of a semiconductor laser diode are exaggerated for clarity.

FIG. 2 is a sectional view illustrating a semiconductor laser diode according to an embodiment of the present invention. Referring to FIG. 2, the semiconductor laser diode according to the present invention includes a substrate 50, and a lower material layer 61, a resonance layer 63, and an upper material layer 65, which are sequentially stacked on the substrate 50.

The lower material layer 61 includes a first compound semiconductor layer 52 as a lower contact layer, which is stacked on the substrate 50 and which has a step, and a lower cladding layer 54 stacked on the first compound semiconductor layer 52. An n-type lower electrode 51 is located on the step of the first compound semiconductor layer 52.

A sapphire substrate or a free standing gallium nitride GaN substrate is used for the substrate 50. The first compound semiconductor layer 52 is formed by an n-GaN based group III-V nitride compound semiconductor layer, and it is preferable that the first compound semiconductor layer 52 is formed by an n-GaN layer. However, the first compound semiconductor layer 52 can be formed by another group III-V compound semiconductor layers that can oscillate laser, in other words, lasing. It is preferable that the lower cladding layer 54 is formed by an n-GaN/AIGaN layer having a predetermined refractive index, however, the lower cladding layer 54 can be formed by another compound that can oscillate laser.

The resonance layer 63 includes a lower waveguide layer 53, an active layer 56, and an upper waveguide layer 55, which are sequentially stacked on the lower cladding layer 54. The upper and lower waveguide layers 55, 53 are formed by a material having a smaller refractive index than the active layer 56. It is preferable that the upper and lower waveguide layers 55, 53 are formed by GaN based group III-V compound semiconductor layers. The lower waveguide layer 53 is formed by an n-GaN layer, and the upper waveguide layer 55 is formed by a p-GaN layer. The active layer 56 is formed by a lasing material, preferably a material oscillating laser beam that has a small critical current value and a stable traverse mode characteristic. It is preferable that the active layer 56 is formed by a GaN based group III-V nitride compound semiconductor material of InₓAl_{y}Ga_{1-x-y}N (0≦x≦1, 0≦y≦1, x+y≦1) including a predetermined amount of Al. Here, the active layer 56 may have any one structure of a multi-quantum well and a single quantum well, and the structure of the active layer 56 does not limit the scope of the present invention.

The upper material layer 65 includes an upper cladding layer 58, which is stacked on the upper surface of the upper waveguide layer 55 while having a protruded ridge 58a at the center, and a second compound semiconductor layer 64 as an ohmic contact layer stacked on the ridge 58a. Here, the refractive index of the upper cladding layer 58 is smaller than that of the upper waveguide layer 55. When the lower cladding layer 54 is formed by an n-type compound semiconductor layer, the upper cladding layer 58 is formed by a p-type compound semiconductor layer. When the lower cladding layer 54 is formed by a p-type compound semiconductor layer, the upper cladding layer 58 is formed by an n-type compound semiconductor layer. In other words, when the lower cladding layer 54 is formed by the n-GaN/AIGaN layer, the upper cladding layer 58 is formed by a p-GaN/AIGaN layer. Similarly, when the first compound semiconductor layer 52 is formed by an n-type compound semiconductor layer, the second compound semiconductor layer 64 is formed by a p-type compound semiconductor layer, and vice-versa. Accordingly, when the first compound semiconductor layer 52 is formed by n-GaN, the second compound semiconductor layer 64 is formed by p-GaN.

The semiconductor laser diode according to the embodiment of the present invention includes a buried layer 68 and a protective layer 69, which is formed on the buried layer 68 to protect the buried layer 68. Here, the buried layer 68 as a passivation layer covers upper edges of the upper cladding layer 58 and the sidewalls of the ridge 58a that is protruding from the center of the upper cladding layer 58. The buried layer 68 is formed of an ordinary passivation material, for example, an oxide including at least one element selected from Si, Al, Zr, and Ta. The protective layer 69 is formed of a material having an excellent etching selectivity and adhesive property to the passivation material, for example, Cr or TiO₂, which is used as a protective mask when etching the buried layer 68. Here, when the protective layer 69 is formed of a metal having an excellent thermal conductivity, the heat generated when the laser device is operating can be efficiently exhausted.

A p-type upper electrode 57 is formed on the ridge waveguide structure where the buried layer 68 and the protective layer 69 are formed. The central portion of the upper electrode 57 contacts the second compound semiconductor layer 64 on the ridge 58a, and the other portion of the upper electrode 57 extends to the shoulders of the upper cladding layer 58.

An n-type electrode 51 is formed on the step of the first compound semiconductor layer 52 as the lower ohmic contact layer. Here, the n-type electrode 51 can be formed on the lower surface of the substrate 50 in order to face the p-type electrode 57, and in this case, it is preferable that the substrate 50 is formed of silicon carbide SiC or GaN.

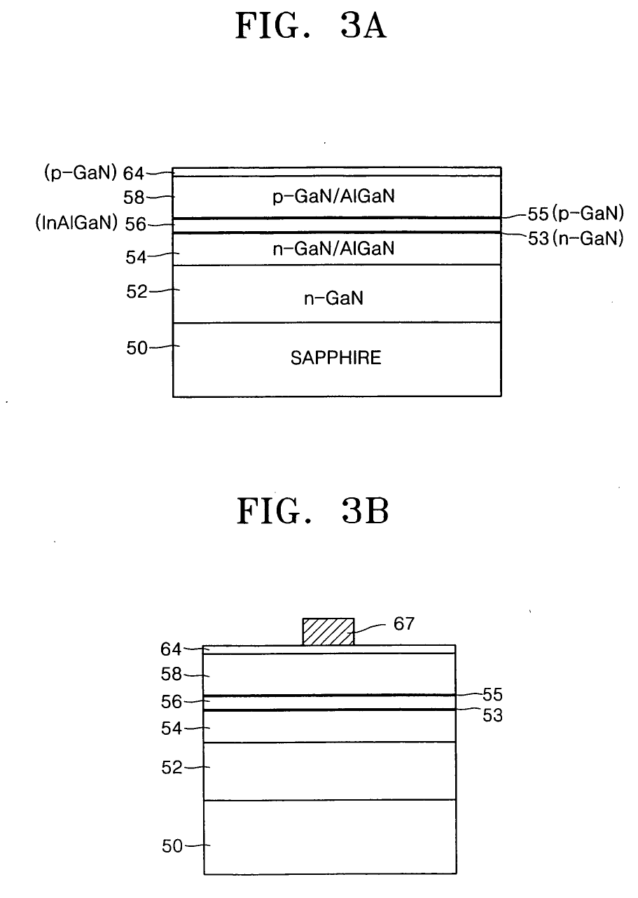

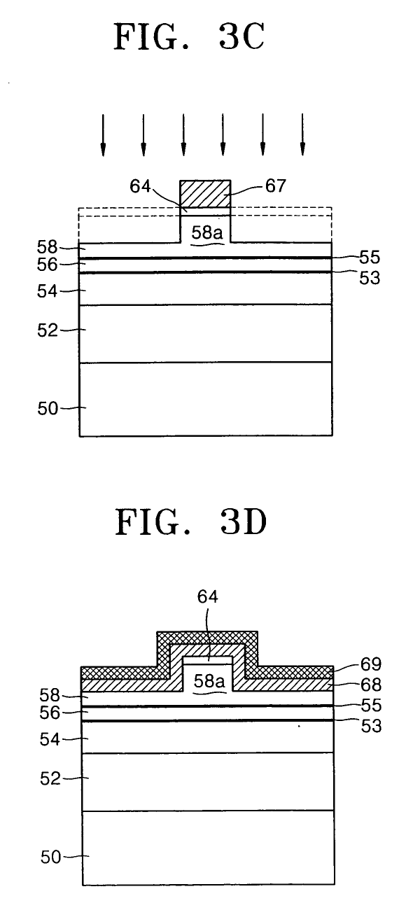

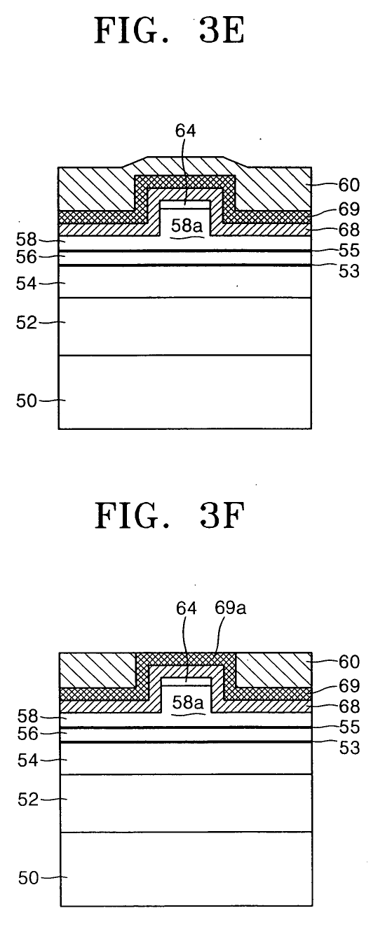

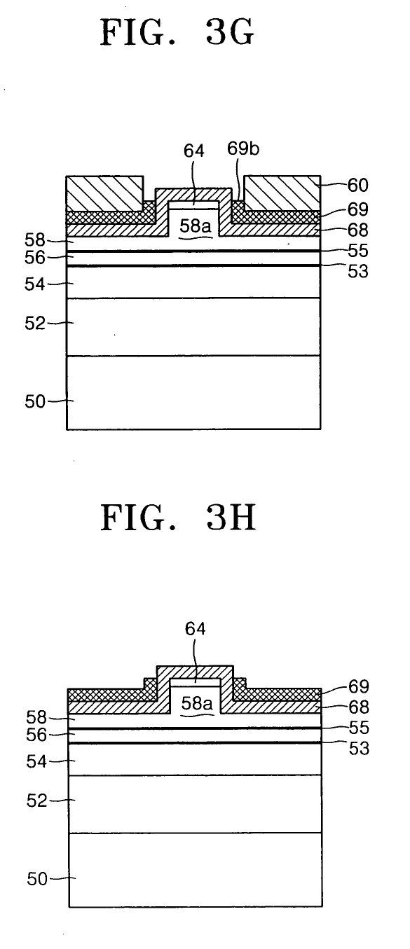

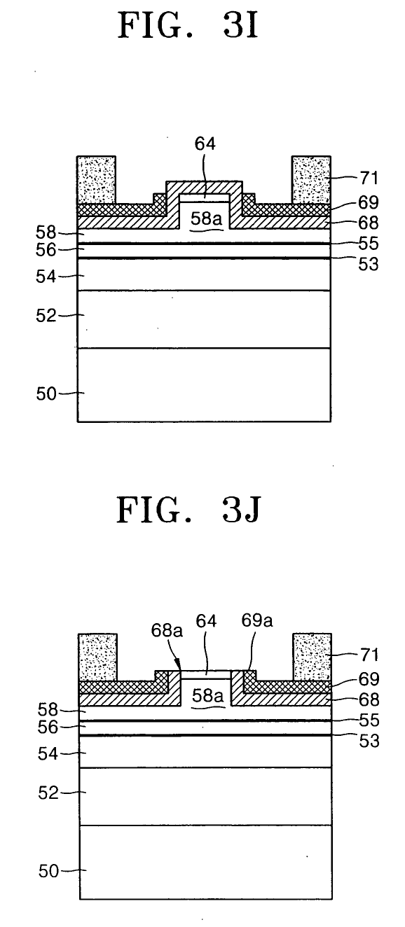

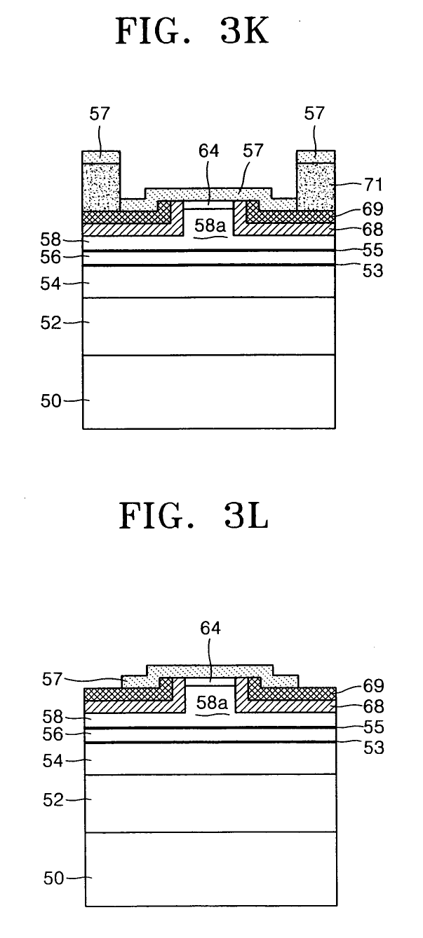

FIGS. 3A through 3L are sectional views illustrating a method of manufacturing the semiconductor laser diode according to the embodiment of the present invention. Here, an etching process for exposing the first compound semiconductor layer 52, in other words, the n-type contact layer, and a process of forming the n-type electrode 51 are omitted. The process of forming the step on the n-type contact layer can be performed before or after the ridge is formed, while etching another layer, or after the protective layer or the upper p-type electrode is formed, by using various methods.

Referring to FIG. 3A, the first compound semiconductor layer 52, the lower cladding layer 54, the lower waveguide layer 53, the active layer 56, the upper cladding layer 55, the upper cladding layer 58, and the upper contact layer, in other words, the second compound semiconductor layer 64 are formed on the substrate 50.

Referring to FIG. 3B, a mask layer 67 for forming the ridge waveguide is formed on the top of the structure, in other words, on the second compound semiconductor layer 64 by coating or patterning a photoresist or depositing or patterning SiO₂.

Referring to FIG. 3C, the portions of the second compound semiconductor layer 64 and the upper cladding layer 58, which are not covered by the mask layer 67 are etched to a predetermined depth by a reactive ion etching RIE, a reactive ion beam etching RIBE, and a chemically assisted ion beam etching CAIBE in order to form the ridge 58a at the center of the upper cladding layer 58.

Referring to FIG. 3D, the SiO₂ buried layer 68 and the TiO₂ or Cr protective layer 69 are sequentially formed on the structure by a depositing method or a sputtering method.

Referring to FIG. 3E, an etch back material layer 60 is formed on the upper cladding layer 58 to a predetermined thickness in order to bury the ridge 58a of the upper cladding layer 58. Here, it is preferable that the etch back material layer 60 is formed by spin coating the photoresist, because the etch back material layer 60 should be formed to a thickness to sufficiently bury the ridge 58a.

Referring to FIG. 3F, the surface of the etch back material layer 60 is planarized by dry etching. Here, the etch back material layer 60 is etched by using an RIE gas including main O₂ gas, additional Cl₂ and CF₄ gas, such that the protective layer 69 has an etch selectivity against the photoresist as the etch back material layer 60. When the etch back material layer 60 is etched by RIE, the surface of a protruding unit 69a of the protective layer 60 is exposed at the upper portion of the ridge 58a. Here, the protective layer 69, especially the protruding unit 69a operates as an etch stop layer.

Referring to FIG. 3G, the protruding unit 69a of the protective layer 69 is etched to expose a portion of the buried layer 68, which is on the top of the ridge 58a, through an opening 69B of the protective layer 69. Here, the protruding unit 69a may be dry etched or wet etched. For example, when the protective layer 69a is formed of Cr, the protruding unit 69a is etched by using HCI/HNO₃ or Cr etchant. When the protective layer 69a is formed of TiO₂, the protruding unit 69A is wet etched by using phosphoric acid or dry etched by using a reactive gas. After the buried layer 69 is exposed, the etch back material layer 60 is removed as shown in FIG. 3H.

Referring to FIG. 31, a lift-off layer having an opened portion corresponding to the ridge 58a is formed by a photolithography process using a photoresist, in order to form the p-type upper electrode.

Referring to FIG. 3J, the portion of the buried layer 68 exposed through the opening 69b of the protective layer 69 is etched by using HF in order to form the contact hole 68a in the buried layer 68 through which the upper surface of the ridge 58a is exposed.

Referring to FIG. 3K, a metallic material 57 for forming the p-type upper electrode is deposited on the upper surface of the structure.

Referring to FIG. 3L, the lift-off layer and the metallic material thereon are removed by a lift-off process using wet etching so that the p-type upper electrode 57 is formed.

In the lift-off process, the contact hole 68a may be formed before the lift-off layer is formed. However, in this case, when the contact hole 68a is formed, the second compound semiconductor layer 64 formed on the ridge 58a is exposed to air through the contact hole 68a until the lift-off layer is formed. Accordingly, the second compound semiconductor layer 64 is affected from the outside. Therefore, as described with reference to FIGS. 31 through 3L, it is preferable that the contact hole 68a be formed after the lift-off layer is formed, and the second compound semiconductor layer 64 is covered to form the metallic material.

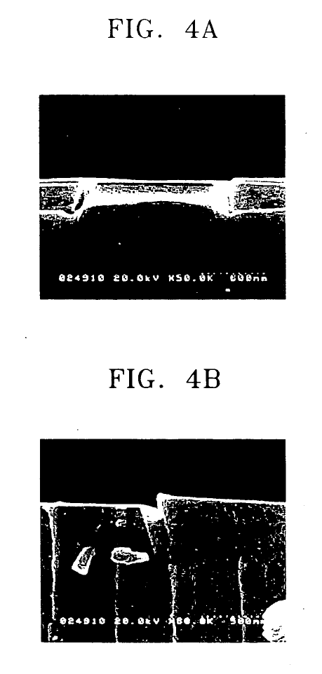

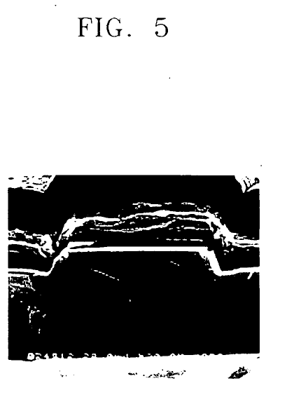

FIG. 4A is an SEM photograph illustrating the result of wet etching of a conventional SiO₂ buried layer, and FIG. 4B is an SEM photograph illustrating the result of wet etching of the buried layer on which the protective layer is formed according to the embodiment of the present invention. Here, the thicknesses of the buried layers shown in FIGS. 4A and 4B are the same, and the wet etching conditions of the buried layers are the same. The buried layer shown in the SEM photograph of FIG. 4A is over etched so that the sidewalls of the ridge are removed. The buried layer shown in the SEM photograph of FIG. 4B is properly etched.

FIG. 5 is an SEM photograph illustrating the laser diode manufactured according to the embodiment of the present invention.

The method of manufacturing the laser diode according to the embodiment of the present invention self-aligns the contact hole to the upper surface of the ridge and prevents over etching of the buried layer when forming the contact layer. Accordingly, the current leakage from the ridge waveguide structure can be efficiently prevented, and the heat generated from the ridge waveguide structure can be efficiently exhausted. Here, the protective layer operates as the etch stop layer when etching the etch back material layer so that the safety and reliability of the processes can be secured. In addition, the height of the material buried at the sides of the ridge can be easily controlled. According to the present invention, the thickness of the buried layer can be sufficiently increased, and the number of materials that can be used as the buried layer is increased.

While this invention has been particularly shown and described with reference to preferred embodiment thereof, it will be understood by those skilled in the art that various changes in form and details may be made therein without departing from the spirit and scope of the invention as defined by the appended claims.

What is claimed is:

1. A laser diode comprising:
a substrate;
a lower material layer formed on the substrate;
a resonance layer formed on the lower material layer;
an upper material layer formed on the resonance layer and having a ridge at the top;
a buried layer having a contact hole corresponding to the ridge of the upper material layer;
a protective layer formed of a material different from the material of the buried layer, and having an opening corresponding to the contact hole of the buried layer; and
an upper electrode formed on the protective layer to contact an upper surface of the ridge through the contact hole.

2. The laser diode of claim 1, wherein the lower material layer includes:
a first compound semiconductor layer stacked on the substrate; and
a lower cladding layer stacked on the first compound semiconductor layer.

3. The laser diode of claim 2, wherein the first compound semiconductor layer is an n-GaN based group III-V nitride semiconductor layer.

4. The laser diode of claim 2, wherein the lower cladding layer is an n-GaN/AIGaN layer.

5. The laser diode of claim 1, wherein the resonance layer further includes:
a lower waveguide layer stacked on the lower cladding layer and having a refractive index larger than that of the lower cladding layer;
an active layer stacked on the upper surface of the lower waveguide layer to generate a laser beam; and
an upper waveguide layer stacked on the active layer.

6. The laser diode of claim 5, wherein the refractive indexes of the upper and lower waveguide layers are lower than the refractive index of the active layer.

7. The laser diode of claim 5, wherein the active layer is a GaN based group III-V nitride compound semiconductor layer of InₓAl_{y}Ga_{1-x-y}N where 0≦x≦1, 0≦y≦1, and x+y≦1.

8. The laser diode of claim 1, wherein the upper material layer includes:
an upper cladding layer stacked on the upper waveguide layer and having the ridge and a refractive index smaller than that of the upper waveguide layer; and
a second compound semiconductor layer formed on the ridge.

9. The laser diode of claim 8, wherein the upper cladding layer is a p-GaN/AIGaN layer.

10. The laser diode of claim 8, wherein the second compound semiconductor layer is a p-GaN based group III-V nitride semiconductor layer.

11. A manufacturing method of a laser diode, the method comprising:
forming a laser oscillating structure including a substrate, a resonance layer on the substrate, and cladding layers formed on and under the resonance layer and having a ridge protruding to a predetermined height;
forming a buried layer on top of the structure to cover the surface of the ridge;
sequentially forming a protective layer and an etch back material layer on the surface of the buried layer;
etching the etch back material layer by an etch back process to a predetermined depth to expose a portion of the protective layer at the upper direction of the ridge;
removing the portion of the protective layer, which is not covered by the etch back material layer, by using an etchant to form an opening which exposes a portion of the surface of the buried layer on the ridge;
removing the etch back material layer remained on the buried layer;
forming a contact hole by etching the portion of the buried layer, which is exposed through the opening of the protective layer; and
forming an upper electrode that contacts to the top surface of the ridge through the contact hole on the protective layer.

12. The method of claim 11, wherein the forming of the layer oscillating structure further includes:
forming a lower material layer including a lower cladding layer, on the substrate;
forming a resonance layer including an active layer, on the lower material layer; and
forming an upper material layer, which includes an upper cladding layer and a contact layer and having the ridge protruding to a predetermined height, on the resonance layer.

13. The method of claim 11, wherein the forming of the lower material layer further includes:
forming a first compound semiconductor layer on the substrate; and
forming the lower cladding layer on the first compound semiconductor layer.

14. The method of claim 13, wherein the first compound semiconductor layer is formed of n-GaN based group III-V nitride.

15. The method of claim 13, wherein the lower cladding layer is formed of n-GaN/AIGaN.

16. The method of claim 11, wherein the forming of the resonance layer further includes:
forming a lower waveguide layer having a refractive index larger than that of the lower cladding layer, on the lower cladding layer;
forming an active layer that generates a laser beam, on the lower waveguide layer; and
forming an upper waveguide layer on the active layer.

17. The method of claim 16, wherein the upper and lower waveguide layers are formed of materials having refractive indexes smaller than that of the active layer.

18. The method of claim 17, wherein the upper and lower waveguide layers are formed of GaN based group III-V compound.

19. The method of claim 16, wherein the active layer is formed of GaN based group III-V nitride compound of InₓAl_{y}Ga_{1-x-y}N where 0≦x 1, 0≦y≦1, and x+y≦1.

20. The method of claim 12, wherein the forming of the upper material layer further includes:
forming an upper cladding layer having a refractive index smaller than that of the upper waveguide layer, on the upper waveguide layer; and
forming a second compound semiconductor layer on the upper cladding layer.

21. The method of claim 20, wherein the upper cladding layer is formed of p-GaN/AIGaN.

22. The method of claim 20, wherein the second compound semiconductor layer is formed of p-GaN based group III-V nitride.

23. The method of claim 11, further including forming a lift-off layer having an opening at a portion corresponding to the ridge, on the second material layer, after the etch back material layer is removed and before the contact hole is formed.
